(19) United States
(12) Patent Application Publication
(10) Pub. No.: US 2007/0227711 A1
(43) Pub. Date: Oct. 4, 2007

(54) Heat sink

(75) Inventor: Hiroyuki Furuya, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/585,904

(22) Filed: Oct. 25, 2006

(30) Foreign Application Priority Data
Mar. 28, 2006 (JP) 2006-089044

(51) Int. Cl. H05K 7/20

(52) U.S. Cl. 165/135; 361/697; 165/80.3; 165/121

(57) ABSTRACT

A heat sink able to fundamentally suppress unpleasant sound by paying attention to the cause of generation of the unpleasant sound, that is, a heat sink provided with a heat spreader and a plurality of flat plate shaped fins provided on that and aligned in parallel, wherein a tone noise diffusing function unit is added or a tone noise diffusion structure is introduced. By using this function unit or structure, tone noise of substantially a single frequency which forms the basis of the unpleasant sound generated from the plurality of flat plate shaped fins by the cooling air is diffused to tone noise having a plurality of frequencies and the unpleasant sound is reduced.

### BACKGROUND OF THE INVENTION

### Field of the Invention

The present invention relates to a heat sink, for example, a heat sink joined with a CPU, IC, HDD, or other electronic device formed by a heat emitter and promoting heat radiation from the electronic device by cooling air.

In recent years, due to the higher speeds and higher functions and, further, the smaller sizes of electronic devices, the heat generation from the electronic devices further increases. In particular, the CPU forming the central electronic device of a personal computer etc. is a typical example of this.

Cooling of CPUs etc. generating high heat in this way is promoted by heat sinks. Usually, a heat sink is comprised of a plurality of heat radiating fins arranged in parallel at fine intervals. Cooling air is blown from a cooling fan toward these heat radiating fins to promote radiation of heat.

For this reason, noise due to turbulence and whistling of the air is unavoidably generated from the heat radiating fins. Many techniques have been proposed for suppressing that noise even slightly. These proposals have actually lowered that noise level itself considerably.

However, in recent years, while the level of the noise per se has been lowered, the unpleasant sound giving an unpleasant and uncomfortable feeling to the user has become a problem. This unpleasant sound is particularly noticed in a silent room or office etc. Countermeasures for that are desired.

Note that, as known techniques related to the present invention, there are Japanese Patent Publication (A) No. 2002-9475, Japanese Patent Publication (A) No. 2003-249611, Japanese Patent Publication (A) No. 2004-11172, and Japanese Utility Model Publication (A) No. 57-30588.

The heat sink disclosed in Japanese Patent Publication (A) No. 2002-9475 is characterized by adhering an acoustic material to part or all of the side surfaces of the fins and enclosing these by a heat sink cover.

Further, the heat sink disclosed in Japanese Patent Publication (A) No. 2003-249611 employs a configuration connecting free ends of a plurality of aligned fins by connection members extended in directions intersecting with the free ends.

Further, the heat sink disclosed in Japanese Patent Publication (A) No. 2004-111727 employs a structure close to that of Japanese Patent Publication (A) No. 2003-249611, but characterized by forming the connection members as three parallel rods and forming three recesses accommodating these three round rods at end surfaces of the above free ends.

All of the heat sinks disclosed in the above publications are common in the point that the noise generated from the fins is forcibly kept down from force from the outside.

However, the techniques according to Japanese Patent Publication (A) No. 2002-9475, Japanese Patent Publication (A) No. 2003-249611, and Japanese Patent Publication (A) No. 2004-11172 are insufficient in the point of not fundamentally suppressing the above unpleasant sound.

### SUMMARY OF THE INVENTION

The object of the present invention is to provide a heat sink able to fundamentally suppress that unpleasant sound by paying attention to the cause of generation of the unpleasant sound.

To attain the above object, in the present invention, there is provided a heat sink provided with a heat spreader (3) and a plurality of flat plate shaped fins (4) provided on that and aligned in parallel, wherein a tone noise diffusing function unit (11, 21, 31, 41) is added or a tone noise diffusion structure (FIG. 13 to FIG. 15) is introduced. By using this function unit or structure, tone noise of substantially a single frequency which forms the basis of the unpleasant sound generated from the plurality of flat plate shaped fins (4) by the cooling air W is diffused to tone noise having a plurality of frequencies and the unpleasant sound is reduced.

### BRIEF DESCRIPTION OF THE DRAWINGS

The above object and features of the present invention will be more apparent from the following description of the preferred embodiments given with reference to the attached drawings, wherein:

FIG. 1 is a first side view of a heat sink according to a first embodiment according to the present invention;

FIG. 2 is a plan view of a heat sink according to a first embodiment according to the present invention;

FIG. 3 is a second side view of a heat sink according to a first embodiment according to the present invention;

FIG. 4 is a side view of a heat sink according to a second embodiment according to the present invention;

FIG. 5 is a plan view of a heat sink according to a second embodiment according to the present invention;

FIG. 6 is a side view of a heat sink according to a third embodiment according to the present invention;

FIG. 7 is a plan view of a heat sink according to a third embodiment according to the present invention;

FIG. 8 is a side view of a heat sink according to a modification of the third embodiment according to the present invention;

FIG. 9 is a plan view of a heat sink according to a modification of the third embodiment according to the present invention;

FIG. 10 is a front view of a heat sink according to a fourth embodiment according to the present invention;

FIG. 11 is a side view of a heat sink according to a fourth embodiment according to the present invention;

FIG. 12 is a plan view of a heat sink according to a fourth embodiment according to the present invention;

FIG. 13 is a side view of a heat sink according to a fifth embodiment according to the present invention;

FIG. 14 is a side view showing another example of a heat sink according to the fifth embodiment of FIG. 13;

FIG. 15 is a side view of a heat sink according to a modification of the fifth embodiment according to the present invention;

FIG. 16 is a graph showing a tone noise characteristic when using a conventional heat sink;

FIG. 17 is a graph showing the tone noise characteristic when using a heat sink of a first embodiment according to the present invention;

FIG. 18 is a graph showing the tone noise characteristic when using a heat sink of a fourth embodiment according to the present invention;

FIG. 19 is a front view of a conventional heat sink;

FIG. 20 is a side view of a conventional heat sink; and

FIG. 21 is a plan view of a conventional heat sink.

### DESCRIPTION OF THE PREFERRED EMBODIMENTS

Preferred embodiments of the present invention will be described in detail below while referring to the attached figures.

A heat sink of the present invention is a heat sink provided with a heat spreader and a plurality of flat plate shaped fins provided on the heat spreader and aligned in parallel adjacent to each other, characterized in that, here, a tone noise diffusing function unit or a tone noise diffusing structure for diffusing tone noise of substantially a single frequency (specific frequency) generated from the plurality of flat plate shaped fins by cooling air to tone noise having a plurality of frequencies is formed.

Here, when considering the nature of the “unpleasant sound”, the characteristic feature of the sound resides in that the frequency spectrum of that unpleasant sound exhibits a peculiar characteristic feature. Specifically, the sound exhibits a specific spectrum having substantially a single frequency. It is known with human senses, as opposed to white noise, tone noise concentrated to a certain specific frequency gives an uncomfortable feeling to people. Namely, the unpleasant sound generated from a heat sink is tone noise comprised of sound having such a single spectrum.

Further considering the cause of generation of such tone noise, the following fact@ is clarified. The structure of a heat sink is generally a structure comprised of a large number of flat plate shaped fins aligned strictly at equal intervals where the cooling air is blown to these aligned fins at almost a constant air speed. The above tone noise is comprised of sounds having the same specific frequency superimposed over each other due to such a “constant property” of a cooling mechanism and appears as a single peak sound. Accordingly, by eliminating the above constant property in the structure of the heat sink and conversely introducing a “random property”, the generation of the unpleasant sound described above can be fundamentally suppressed. This is the point of the present invention. The object of the present invention can be achieved by the above-described “tone noise diffusing function unit”. The concrete configuration of the function unit will be explained later.

Note that Japanese Utility Model Publication (A) No. 57-30588 discloses thinking close to the above-explained thinking in principle, but fundamentally differs from the configuration of the present invention explained later in the point that it employs an interference plate suppressing not the whistling sound, but resonance due to the “Karman's vortex” and the point that it arranges the interference plate outside of the fins.

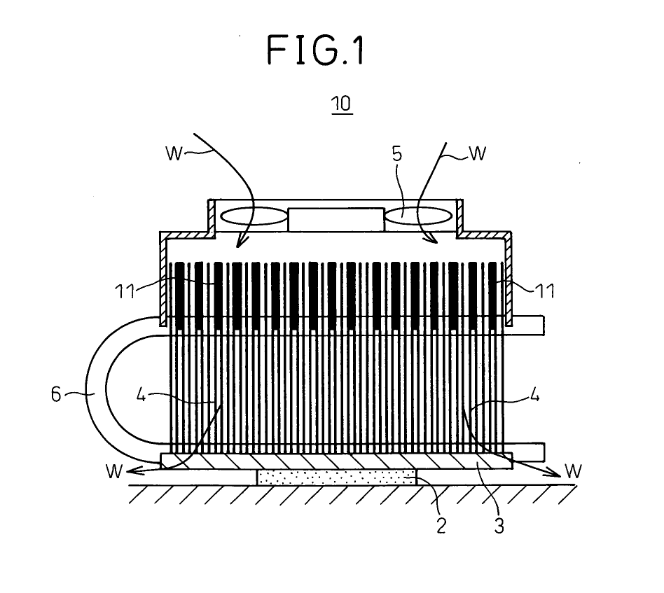

A first embodiment of the above “tone noise diffusing function unit” (FIG. 1 to FIG. 3) just inserts and fixes plates made of metal or plastic between adjacent fins with a random pattern so as to realize the above “random property”. The plates are tone noise diffusing plates. Not only is there is the effect of suppression of the unpleasant sound, but also the rigidity of the free ends of the large number of fins is raised and the generation of resonant sounds can be suppressed. Further, if forming the tone noise diffusing plates by metal plates made of copper or the like, the mutual heat transmission efficiencies among the free ends of the large number of fins are improved and a heat radiation promotion effect further promoting heat radiation is obtained.

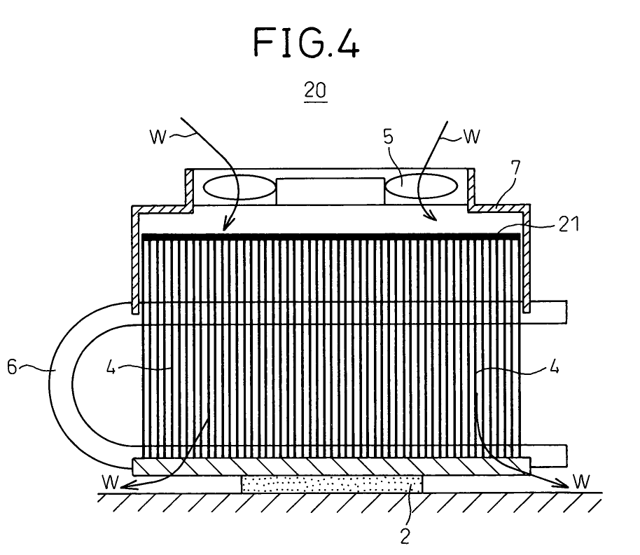

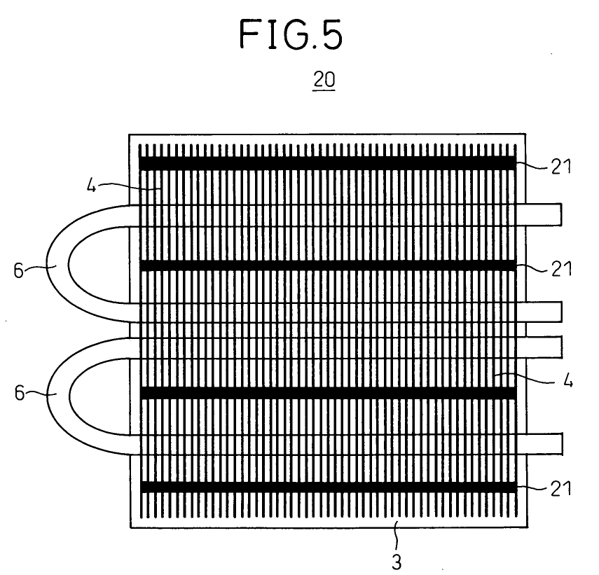

A second embodiment of the above tone noise diffusing function unit (FIG. 4 and FIG. 5), in the same way as the first embodiment, naturally obtains the unpleasant sound suppression effect and also raises the rigidity of free ends of the large number of fins and obtains the heat radiation promotion effect described above. Further, this second embodiment only adheres tapes, therefore the number of manufacturing steps is not increased either.

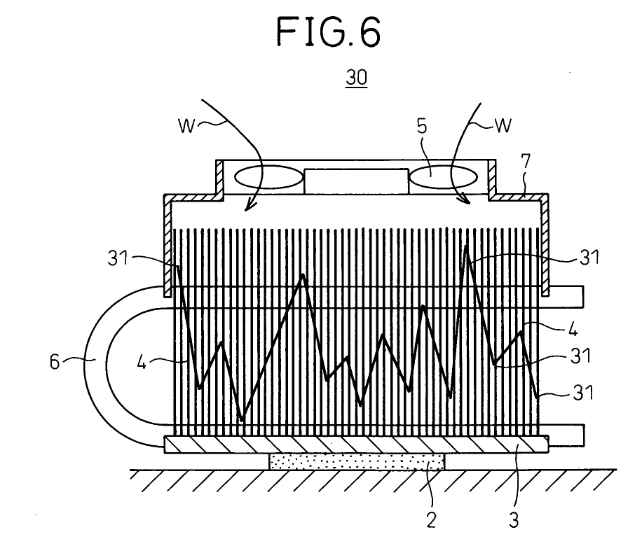

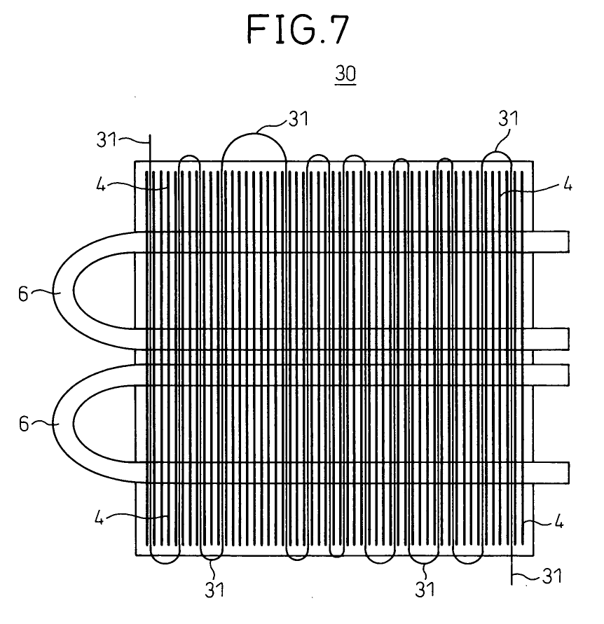

A third embodiment of the above tone noise diffusing function unit (FIG. 6 and FIG. 7) can be accomplished by a simple material such as a wire or a thread.

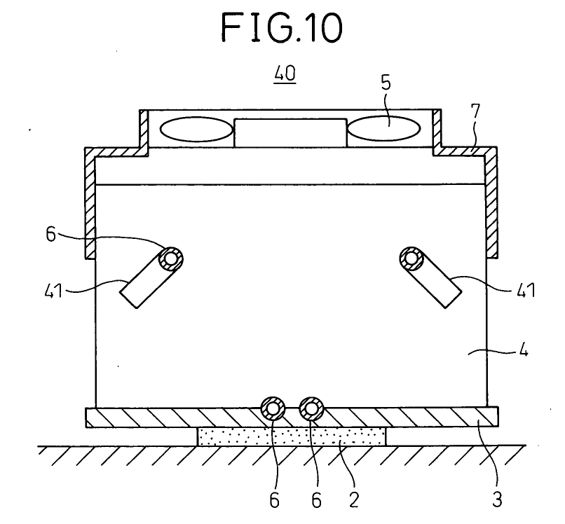

A fourth embodiment of the above tone noise diffusing function unit (FIG. 10 to FIG. 12) naturally obtains the unpleasant sound suppression effect and further can improve the heat transmission efficiencies between the heat pipe and the large number of fins and among the large number of fins. Further, it has the effect that the tone noise diffusing strips (41) become guide plates which smoothly guide the cooling air to the outside of the heat sink.

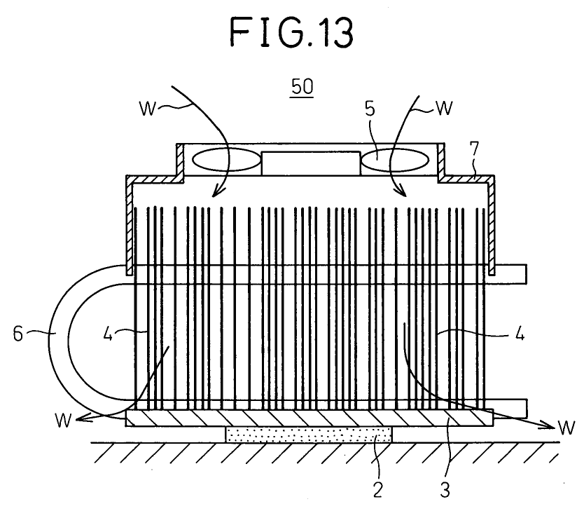

The above tone noise diffusing “structure” (FIG. 13 to FIG. 15) naturally obtains the unpleasant sound suppression effect and has the function of increasing the turbulence of the cooling air.

In order to clarify the effects brought about according to the present invention, first, an explanation will be given of a conventional heat sink with reference to the drawings. Note that the fundamental structure of the heat sink according to the present invention explained above is shown in the drawings as examples.

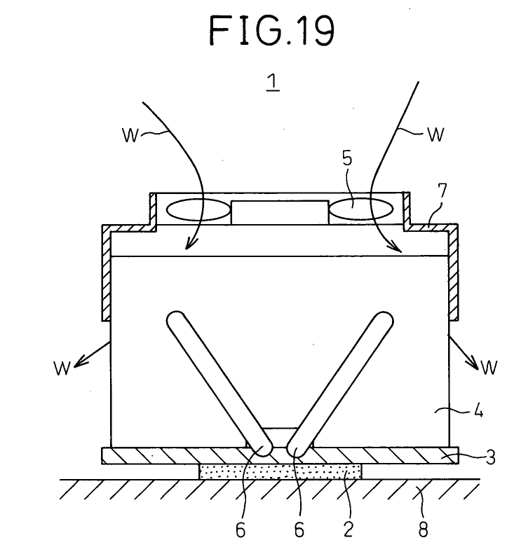

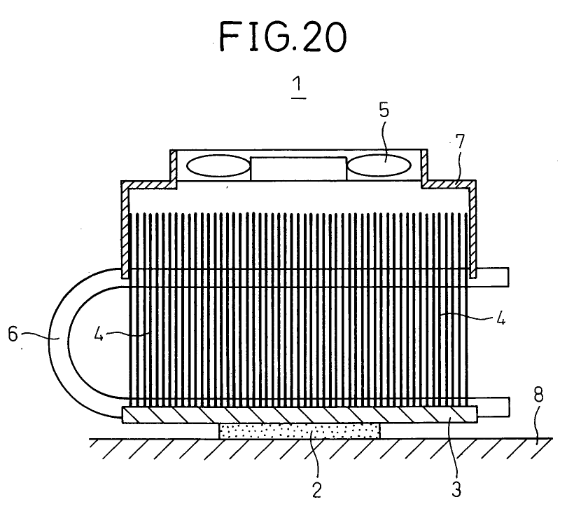

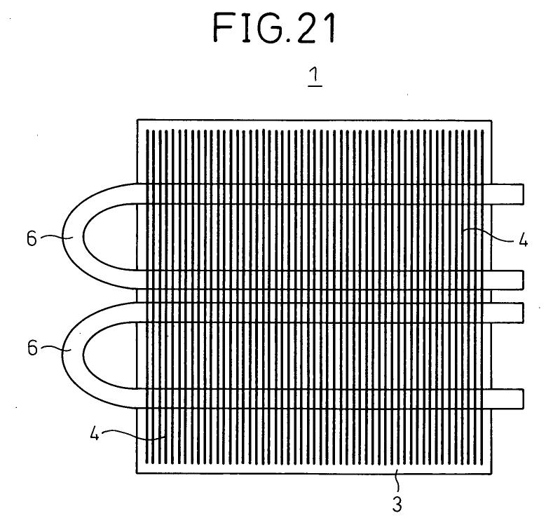

FIG. 19 shows a front view of a conventional heat sink; FIG. 20 shows a side view thereof; and FIG. 21 shows a plan view thereof.

Referring to FIG. 19 first, an electronic device forming a heat emitting device, i.e., a CPU 2 as a representative example, is mounted on an IC substrate 8. The heat generated from this CPU 2 is transmitted to an heat spreader (HS) 3 made of for example copper. Heat is radiated over broad range of this spreader 3.

On the heat spreader 3 increased in range of heat radiation, a large number of flat plate shaped fins 4 made of for example aluminum are aligned in parallel adjacent to each other. The lower end of each flat plate shaped fin 4 is fixed to the surface of the heat spreader 3 by for example brazing and becomes the fixed end.

On the other hand, the upper end of each flat plate shaped fin 4 becomes the free end and becomes the point capturing the cooling air W from the cooling fan 5. That captured cooling air W passes through spaces between adjacent fins and is diffused to the outside of the heat sink 1 together with the heat.

In the heat sink 1 shown in the figure, in order to further raise the heat radiation effect, heat pipes 6 are built in the group of flat plate shaped fins. In the present figure, two U-shaped heat pipes 6 are illustrated, but the number is not limited to this. There may be one or three or more pipes as well. Further, in the figure, two U-shaped heat pipes 6 are arranged in a V-configuration when seen from the front (FIG. 19), but this is to only avoid contact with the other electronic devices on the above IC substrate 8.

In the conventional heat sink 1 shown in FIG. 19 to FIG. 21, as already explained in detail, due to the “constant property” described above that the constant speed cooling air W abuts against the large number of flat plate shaped fins 4 aligned at equal intervals, tone noise having the same specific frequency is superimposed and heard as one large peak sound. This is the afore-mentioned “unpleasant sound” and gives an uncomfortable feeling to the human ear.

Therefore, the present invention, as explained above, proposes a heat sink 1 provided with a heat spreader 3 and a plurality of flat plate shaped fins 4 provided on this heat spreader 3 and aligned in parallel adjacent to each other wherein a “tone noise diffusing function unit” or a “tone noise diffusing structure” for diffusing tone noise having substantially a single frequency generated from a plurality of flat plate shaped fins 4 by the cooling air W to tone noise of a plurality of frequencies.

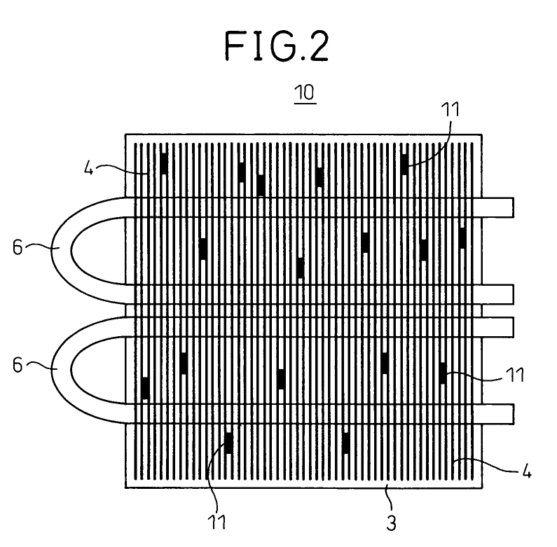

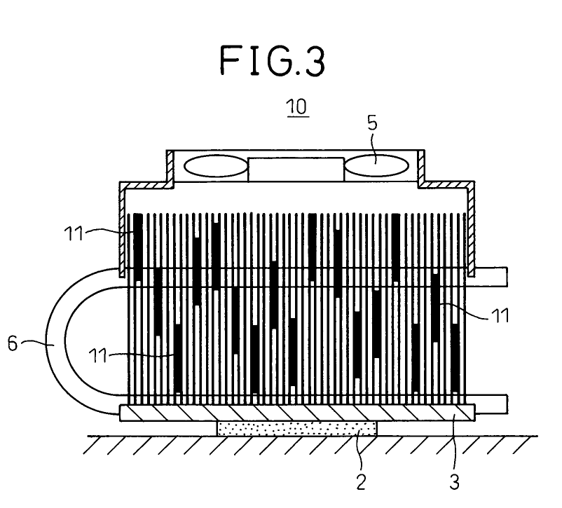

FIG. 1 shows a first side view of a heat sink 10 according to a first embodiment according to the present invention; FIG. 2 shows a splan view thereof; and FIG. 3 shows a second side view thereof. Note that throughout all the drawings, the same components are indicated by same reference numerals or symbols.

Here, the above tone noise diffusing function unit according to the present invention is constituted by tone noise diffusing plates 11 inserted and fixed between adjacent flat plate shaped fins 4 (FIG. 1 to FIG. 3). The point to be noted here resides in that the plurality of tone noise diffusing plates 11 are randomly arranged in a width direction of the flat plate shaped fins 4 (up/down direction in the figure) when seen from the top surfaces of the plurality of flat plate shaped fins 4 (FIG. 2). Due to this, the above mentioned “constant property” is eliminated to realize the above mentioned “random property” and diffuse the frequency of the peak sound, that is, tone noise, due to the superimposition of sound having a specific frequency and suppress the generation of unpleasant sound. Another aspect of the “random property” is shown in FIG. 3. According to what is shown in FIG. 3, the plurality of tone noise diffusing plates 11 are arranged at random in a height direction of the plurality of flat plate shaped fins 4 (up/down direction in the figure) when seen from side surfaces of the plurality of flat plate shaped fins 4 (FIG. 3).

With both the first mode of the random property shown in FIG. 2 described above and the second mode of the random property shown in FIG. 3 described above, the effect of suppression of the unpleasant sound is good. When combining these first mode and second mode, the suppression effect becomes even better.

The tone noise diffusing plates 11 having such an effect of suppression of unpleasant sound are rectangularly shaped and can be made from a metal such as aluminum, copper, or iron or from a plastic. When they are made of plastic, this is useful for lightening the weight, while when they are made of a metal, the conduction of heat between adjacent flat plate shaped fins is further improved and also the cooling effect rises.

Such tone noise diffusing plates 11 are, as explained above, inserted and fixed between adjacent fins (4). These may be inserted and fixed by (a) press-fitting the diffusing plates 11 into the spaces between adjacent fins, (b) press bonding the diffusing plates 11 between adjacent fins, (c) soldering the diffusing plates 11 to the adjacent fins, and (d) attaching double-faced adhesive tape or a binder to the diffusing plates 11 and inserting the plates into the spaces between adjacent fins.

FIG. 4 shows a side view of a heat sink 20 according to a second embodiment according to the present invention; and FIG. 5 shows a plan view thereof.

The heat sink 20 according to the second embodiment is a heat sink provided with a heat spreader 3 and a plurality of flat plate shaped fins 4 provided on this heat spreader 3 and aligned in parallel adjacent to each other, wherein a tone noise diffusing function unit is formed for diffusing tone noise having substantially the single frequency generated from a plurality of flat plate shaped fins 4 by cooling air W to tone noise having a plurality of frequencies, characterized in that this tone noise diffusing function unit is constituted by a plurality of tone noise diffusing tapes 21 laid on the top surfaces of the plurality of flat plate shaped fins 4 in directions intersecting with the free ends (upper ends) of these flat plate shaped fins 4. Note that these diffusing tapes 21 may be provided not only in parallel to each other (FIG. 5), but also to intersect with each other or be inclined.

By providing the tone noise diffusing tapes 21 in this way, turbulence of air is created at four locations (FIG. 5) on the top surfaces of the groups of the flat plate shaped fins (4) forming the capturing parts of the cooling air W so as to realize the above-explained “random property”. Namely, the peak sound (tone noise) due to the superimposition of sounds having the specific frequency can be diffused.

This tone noise diffusing tape 21 can be constituted by a metal tape or a heat conducting tape provided with tackiness. As that tape, for example there are “5509S” made by SUMITOMO 3M CORPORATION and “Aluminum Tape” made by Sekisui Chemical Co., Ltd.

By providing the tackiness as described above, the manufacturing work becomes easy, but even when such tackiness is not provided, the above-described metallic tape or heat conduction tape 21 may be used to press down the group of flat plate shaped fins from above.

By the introduction of such tape 21, not only is the unpleasant sound suppressed, but also the rigidity of the top parts of the fins rises. Further, by using the good heat conduction tape 21, the heat conduction between the top ends of the flat plate shaped fins 4 further rises and the cooling efficiency becomes better.

FIG. 6 shows a side view of a heat sink 30 according to a third embodiment according to the present invention; and FIG. 7 shows a plan view thereof.

The heat sink 30 according to the third embodiment is a heat sink provided with a heat spreader 3 and a plurality of flat plate shaped fins provided on this heat spreader 3 and aligned in parallel adjacent to each other, wherein a tone noise diffusing function unit is formed for diffusing tone noise having substantially the single frequency generated from a plurality of flat plate shaped fins 4 by cooling air W to tone noise having a plurality of frequencies is formed, characterized in that this tone noise diffusing function unit is constituted by wires 31 arranged at random locations between adjacent flat plate shaped fins 4 along the flat plate shaped fins 4 in the height direction of the flat plate shaped fins 4.

By introducing the wires 31 in this way, the frequency of the whistling sound generated from the spaces between adjacent fins can be made variable, and the superimposition of peak sounds having a single frequency on each other can be prevented. Namely, the suppression of unpleasant sound becomes possible.

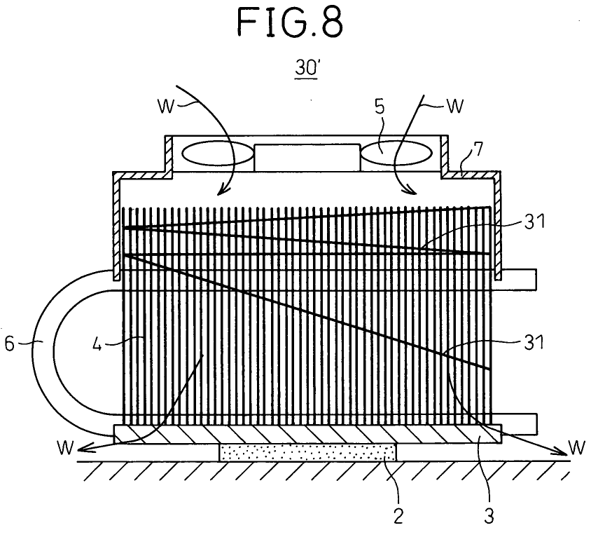

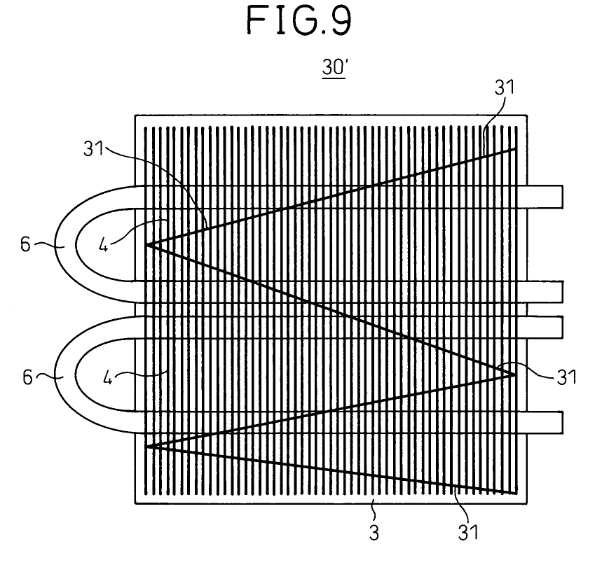

FIG. 8 shows a side view of a heat sink 30′ according to a modification of the third embodiment; and FIG. 9 shows a plan view thereof.

The heat sink 30′ according to this modification of the third embodiment is, in the same way as above third embodiment, a heat sink provided with a heat spreader 3 and a plurality of flat plate shaped fins 4 provided on this heat spreader 3 and aligned in parallel adjacent to each other, wherein a tone noise diffusing function unit is formed for diffusing tone noise having substantially a single frequency generated from a plurality of flat plate shaped fins 4 by cooling air W to tone noise having a plurality of frequencies, characterized in that this tone noise diffusing function unit is constituted by a plurality of wires 31 laid so as to laterally pass through the plurality of flat plate shaped fins 4 in directions random relative to each other.

In the case of this modification of the third embodiment as well, by the introduction of wires 31, the frequency of the whistling sound generated from the spaces between adjacent fins is made variable, superimposition of peak sounds having a single frequency is prevented, and generation of the unpleasant sound can be suppressed.

According to the third embodiment and the modification of the third embodiment described above, the prevention of the unpleasant sound can be accomplished by welding or bonding the wires 31 to the flat plate shaped fins 4 or forming holes in the fins 4 and passing the wires 31 through those holes. Alternatively, the method of winding the wires 31 around the flat plate shaped fins 4 or fixing these by screws may be used. In any case, this can be accomplished by an extremely simple material (wire or thread).

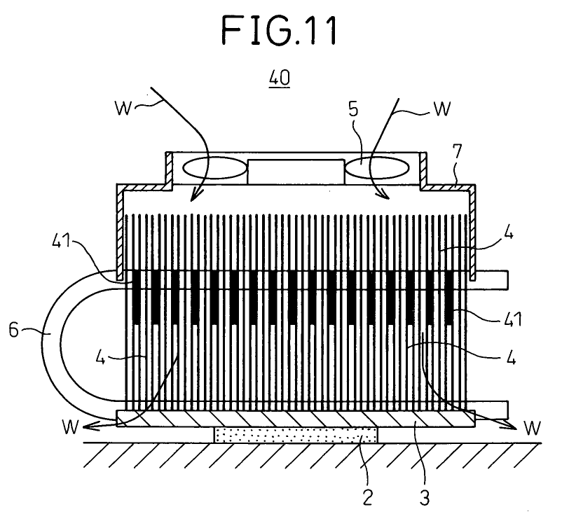

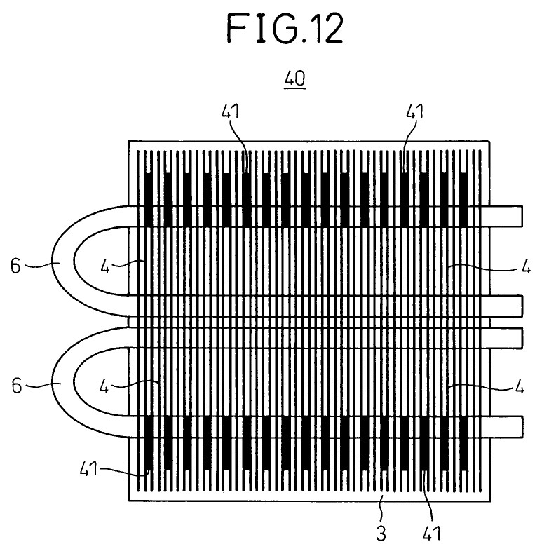

FIG. 10 shows a front view of a heat sink 40 according to a fourth embodiment according to the present invention; FIG. 11 shows a side view thereof; and FIG. 12 shows a plan view thereof.

The heat sink 40 according to this fourth embodiment is a heat sink provided with a heat spreader 3, a plurality of flat plate shaped fins 4 provided on this heat spreader 3 and aligned in parallel adjacent to each other, and at least one heat pipe 6 laid so as to penetrate through these flat plate shaped fins 4 in order to radiate the heat on the heat spreader 3 from these flat plate shaped fins 4, in which a tone noise diffusing function unit is formed for diffusing tone noise having substantially a single frequency generated from the plurality of flat plate shaped fins 4 by cooling air W to tone noise having a plurality of frequencies.

Here, the tone noise diffusing function unit according to the fourth embodiment is constituted by tone noise diffusing strips 41 having first ends bonded to the heat pipe 6 and inserted and fixed between adjacent flat plate shaped fins 4.

By introducing the tone noise diffusing strips 41 in this way, variation can be imparted to frequencies of the whistling sound generated from spaces between adjacent fins and the superimposition of peak sounds having a single frequency on each other can be prevented. Namely, the generation of the unpleasant sound is suppressed.

Further, the tone noise diffusing strips 41 are preferably arranged tilted facing each other as shown in FIG. 10, that is, in directions along the flow of the cooling air W. By imparting inclination in the open tilted facing state in this way, the flow of the cooling air W carrying heat to the outside of the heat sink becomes smooth.

The tone noise diffusing plates 41 are rectangularly shaped and can be made from a metal such as aluminum, copper, or iron or from a plastic. When they are made of plastic, this is useful for lightening the weight, while when they are made of a metal, the conduction of heat between adjacent flat plate shaped fins is further improved and also the cooling effect rises.

Such tone noise diffusing plates 41 are, as explained above, inserted and fixed between adjacent fins (4) while bonded with the heat pipe 6. These may be inserted and fixed by (a) press-fitting the diffusing plates 41 into the spaces between adjacent fins, (b) press bonding the diffusing plates 11 between adjacent fins, (c) soldering the diffusing plates 41 to the adjacent fins, and (d) attaching double-faced adhesive tape or a binder to the diffusing plates 41 and inserting the plates into the spaces between adjacent fins.

Note that the heat pipe 6 and the diffusing strips 41 may be joined by soldering or bonding or may simply contact each other.

The heat sinks (10, 20, 30, 30′, 40) according to the first embodiment to the fourth embodiment described above use tone noise diffusing function units such as the tone noise diffusing plates 11, tone noise diffusing tapes 21, tone noise diffusion use wires 31, and tone noise diffusing strips 41, but the object of the present invention can also be achieved without using such additional members. This is a fifth embodiment according to the present invention.

A heat sink 50 according to a fifth embodiment is a heat sink provided with a heat spreader 3 and a plurality of flat plate shaped fins 4 provided on this heat spreader 3 and aligned in parallel adjacent to each other, in which the overall structure of the plurality of flat plate shaped fins 4 is modified to a “tone noise diffusing structure” diffusing tone noise having substantially a single frequency generated from these flat plate shaped fins 4 by cooling air W to tone noise having a plurality of frequencies.

FIG. 13 shows a side view of the heat sink 50 according to the fifth embodiment according to the present invention. As apparent from the figure, the above-described “tone noise diffusing structure” is characterized in that the alignment pitches between adjacent flat plate shaped fins (4) become non-uniform relative to each other.

In this way, even by making the alignment pitches among flat plate shaped fins non-uniform relative to each other, the already explained “random property” is satisfied. A situation where peak sounds having a single frequency overlap on each other can therefore be prevented. Namely, the generation of unpleasant sound can be prevented.

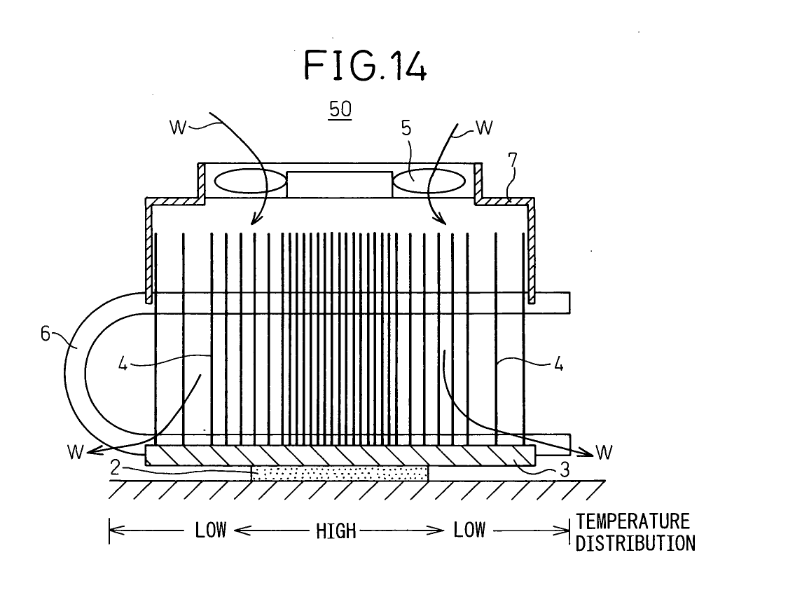

FIG. 14 shows a heat sink 50 exhibiting another example of the fifth embodiment shown in FIG. 13. The characteristic feature of the heat sink 50 shown in the figure resides in that the above-described alignment pitches become denser or sparser in accordance with the level of the temperature distribution on the heat spreader 3. The alignment pitches are more preferably non-uniform than uniform, but when realizing a non-uniform pattern, from the object of the heat sink, most preferably a non-uniform pattern that can raise the heat radiation effect is employed.

Therefore, in the example of FIG. 14 described above, the flat plate shaped fins 4 at the CPU 2 and near that showing the highest temperature in the temperature distribution are aligned “densely” (the cooling effect is large) while being spaced a little from each other, while in the regions around the CPU at which the temperature is relatively low in the temperature distribution, the flat plate shaped fins 4 are aligned “sparsely” (the cooling effect is small) while being largely spaced from each other.

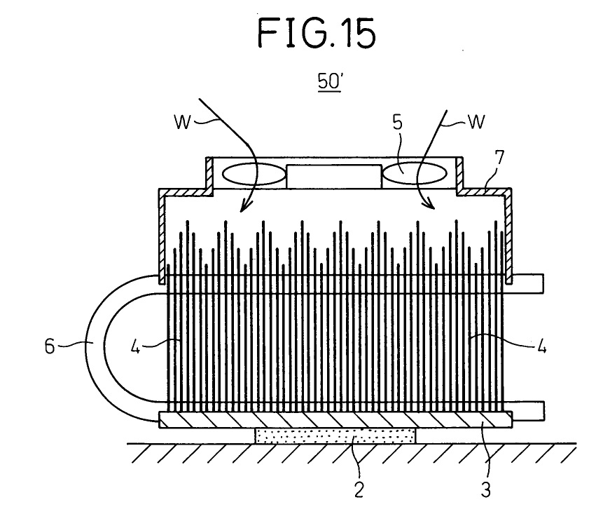

FIG. 15 is a side view of a heat sink 50′ according to a modification of the fifth embodiment according to the present invention. The heat sink 50′ according to this modification of the fifth embodiment is, in the same way as the fifth embodiment described above, a heat sink provided with a heat spreader 3 and a plurality of flat plate shaped fins 4 provided on this heat spreader 3 and aligned in parallel adjacent to each other, wherein the overall structure of the plurality of flat plate shaped fins 4 is modified to a tone noise diffusing structure diffusing tone noise having substantially a single frequency generated from these flat plate shaped fins 4 by cooling air W to the tone noise having a plurality of frequencies, characterized in that the tone noise diffusing structure is modified to a structure that changes heights of flat plate shaped fins 4 randomly so that top surfaces of the flat plate shaped fins 4 do not become flat.

Further, according to the fifth embodiment (FIG. 13 and FIG. 14) and the modification of the fifth embodiment (FIG. 15), in addition to the effect of diffusing tone noise of a specific frequency to noise of a plurality of frequencies, an effect of further reducing the unpleasant sound due to the diffusion of the resonant frequency is provided.

Note that in the modification of the fifth embodiment described above, in FIG. 15, the random property is realized so that the envelopes of the flat plate shaped fins 4 become a repetition of a constant shape (triangle), but the overall envelopes may be shaped so as to give indefinite patterns without repetition.

Finally, the effect of reduction of unpleasant sound by the heat sink according to the present invention is shown by actual measurement values thereof. For comparison, the conventional heat sink 1 (FIG. 19 to FIG. 21), the first embodiment (FIG. 1 and FIG. 2), and the fourth embodiment (FIG. 10, FIG. 11, and FIG. 12) selected from among the various embodiments according to the present invention were compared.

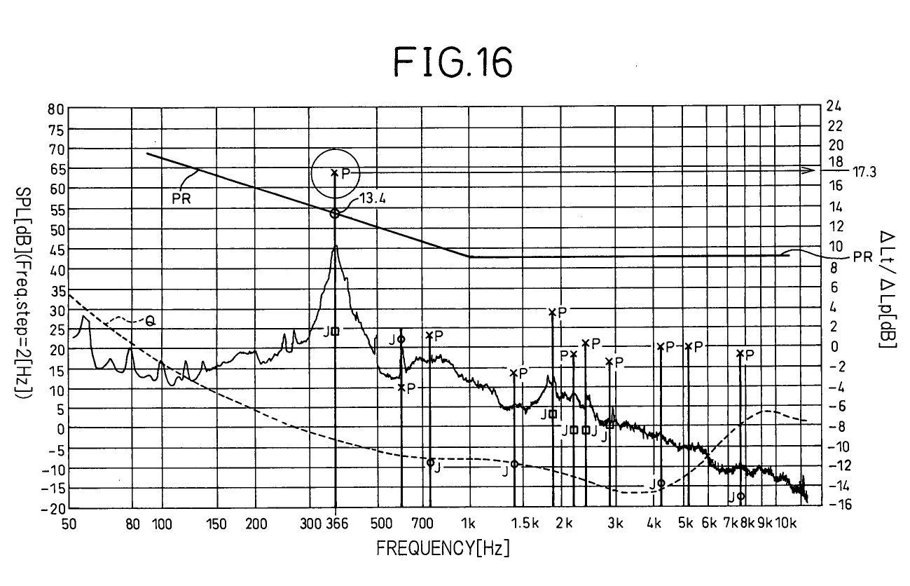

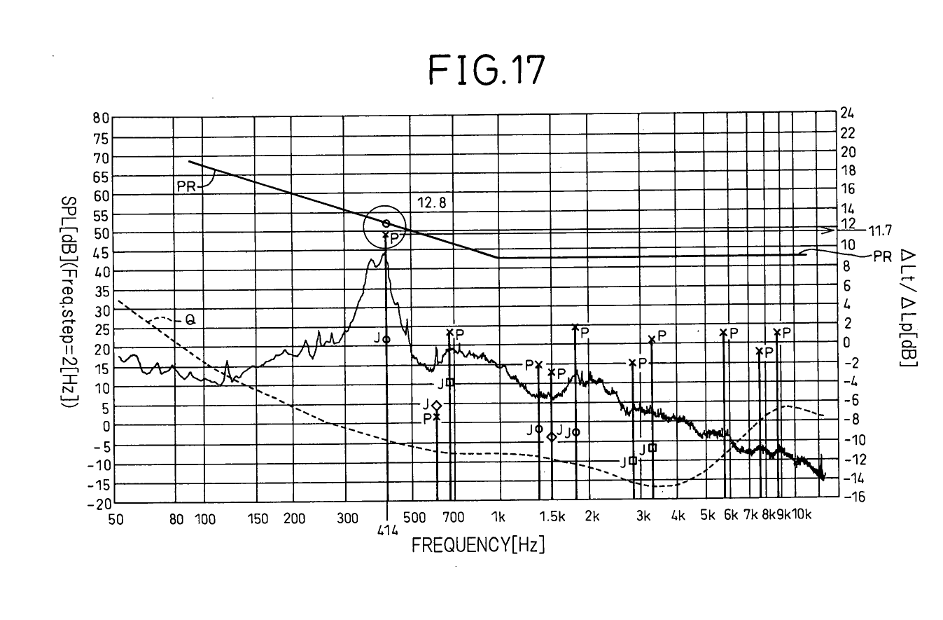

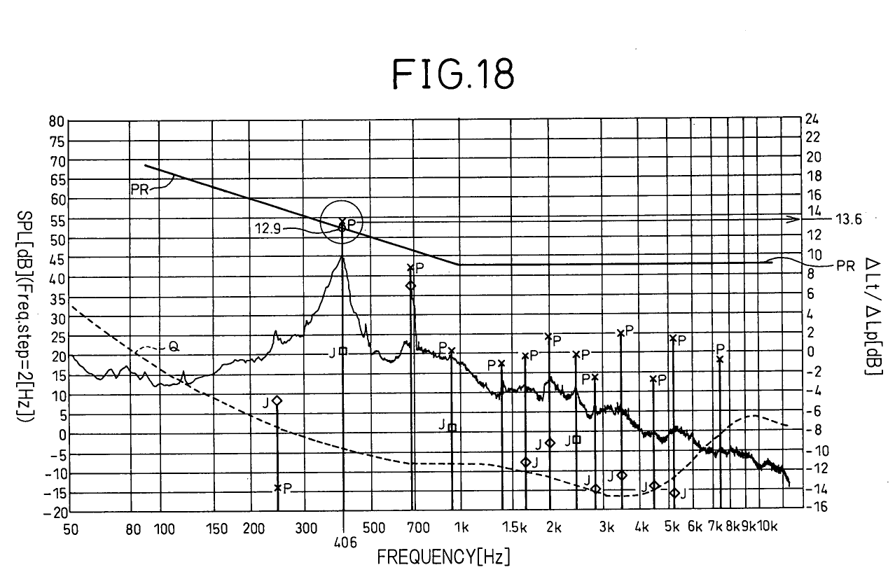

FIG. 16 is a graph showing the tone noise characteristic when using the conventional heat sink 1; FIG. 17 is a graph showing the tone noise characteristic when using the heat sink 10 of the first embodiment according to the present invention; and FIG. 18 is a graph showing the tone noise characteristic when using the heat sink 40 of the fourth embodiment according to the present invention. Note that as methods of objective evaluation of the unpleasant sound, there are the methods prescribed in ISO7779, JIS X7779, and ECMA74. FIG. 16 to FIG. 18 show results by measurement by the prominence ratio (PR) method defined in ECMA74.

In FIG. 16 to FIG. 18, the solid line PR represents a threshold level giving an unpleasant feeling to the human ear. When a peak sound P exceeds this threshold level PR, a person is given an unpleasant feeling. Note that the human ear does not sense a peak sound lower than a level Q indicated by the dotted line.

The point to be noted in FIG. 16 (prior art) is that when using the heat sink 1 shown in FIG. 19 to FIG. 21, the already explained specific frequency (FREQUENCY) is 366 Hz and the PR measurement value at that time becomes 17.3 dB or 3.9 (=17.3−13.4) dB over the PR judgment value 13.4 dB at that time. That is, in the conventional heat sink 1, an unpleasant feeling as much as +3.9 dB over the standard is generated.

On the other hand, the point to be noted in FIG. 17 (first embodiment) is that when using the heat sink 10, the already explained specific frequency (FREQUENCY) is 414 Hz and the PR measurement value at that time becomes 11.7 dB or 1.1 dB less than the PR judgment value 12.8 dB at that time. That is, in the heat sink 10 of the first embodiment, an unpleasant sound −1.1 dB lower than the standard is generated.

In the end, when applying the countermeasure according to the present invention, in comparison with the conventional case, an effect of suppression of unpleasant sound as large as −5.0 (=3.9+1.1) dB is obtained.

In the same way, when viewing FIG. 18 (fourth embodiment), when using the heat sink 40, the already explained specific frequency (FREQUENCY) is 406 Hz and the PR measurement value at that time becomes 13.6 dB or 0.7 (=13.6−12.9) dB over the PR judgment value 12.9 dB at that time. That is, in the heat sink 40 of the fourth embodiment, an unpleasant feeling +0.7 dB over the standard is generated. Accordingly, in comparison with the conventional case, when the countermeasure according to the fourth embodiment of the present invention is applied, the effect of reduction of unpleasant sound of −3.2 (=3.9−0.7) dB is confirmed.

As explained above, according to the present invention, by eliminating the “constant property” of the structure of the conventional heat sink and employing the “random property”, the concentration of tone noise to a specific spectrum is prevented and white noise can be created. Namely, it becomes possible to suppress the unpleasant sound.

While the invention has been described with reference to specific embodiments chosen for purpose of illustration, it should be apparent that numerous modifications could be made thereto by those skilled in the art without departing from the basic concept and scope of the invention.

1. A heat sink provided with a heat spreader and a plurality of flat plate shaped fins provided on the heat spreader and aligned in parallel adjacent to each other, wherein
a tone noise diffusing function unit is formed for diffusing tone noise of a substantially single frequency generated from said plurality of flat plate shaped fins by cooling air to tone noise having a plurality of frequencies,
the tone noise diffusing function unit comprised of tone noise diffusing plates inserted and fixed into spaces between adjacent fins of a plurality of flat plate shaped fins.

2. A heat sink as set forth in claim 1, wherein said plurality of tone noise diffusing plates are randomly arranged in a width direction of the tone noise diffusing plates when seen from top surfaces of said plurality of flat plate shaped fins.

3. A heat sink as set forth in claim 1, wherein said plurality of tone noise diffusing plates are arranged randomly in a height direction of the tone noise diffusing plates when seen from side surfaces of the plurality of flat plate shaped fins.

4. A heat sink as set forth in claim 1, wherein said tone noise diffusing plates are rectangularly shaped and are made by a metal such as aluminum, copper, or iron or a plastic.

5. A heat sink provided with a heat spreader and a plurality of flat plate shaped fins provided on the heat spreader and aligned in parallel adjacent to each other, wherein
a tone noise diffusing function unit is formed for diffusing tone noise of a substantially single frequency generated from said plurality of flat plate shaped fins by cooling air to tone noise having a plurality of frequencies,
the tone noise diffusing function unit comprised of a plurality of tone noise diffusing tapes laid on top surfaces of said plurality of flat plate shaped fins and in directions intersecting with free ends of the plurality of flat plate shaped fins.

6. A heat sink as set forth in claim 5, wherein said tone noise diffusing tapes are constituted by metallic tapes or heat conduction tapes provided with tackiness.

7. A heat sink provided with a heat spreader and a plurality of flat plate shaped fins provided on the heat spreader and aligned in parallel adjacent to each other, wherein
a tone noise diffusing function unit is formed for diffusing tone noise of a substantially single frequency generated from said plurality of flat plate shaped fins by cooling air to tone noise having a plurality of frequencies,
the tone noise diffusing function unit comprised of wires laid between said plurality of flat plate shaped fins at random locations along the flat plate shaped fins in the height direction of the flat plate shaped fins.

8. A heat sink provided with a heat spreader and a plurality of flat plate shaped fins provided on the heat spreader and aligned in parallel adjacent to each other, wherein
a tone noise diffusing function unit is formed for diffusing tone noise of a substantially single frequency generated from said plurality of flat plate shaped fins by cooling air to tone noise having a plurality of frequencies,
the tone noise diffusing function unit comprised of a plurality of wires laid so as to laterally pass through said plurality of flat plate shaped fins in directions random relative to each other.

9. A heat sink as set forth in claim 7, wherein said wires are comprised of metallic wires or threads.

10. A heat sink provided with a heat spreader, a plurality of flat plate shaped fins provided on the heat spreader and aligned in parallel adjacent to each other, and at least one heat pipe laid so as to pass through the flat plate shaped fins in order to radiate the heat on said heat spreader from the flat plate shaped fins, wherein
a tone noise diffusing function unit is formed for diffusing tone noise having a substantially single frequency generated from said plurality of flat plate shaped fins by the cooling air to tone noise having a plurality of frequencies,
the tone noise diffusing function unit comprised of tone noise diffusing strips having first ends bonded to said heat pipe and inserted and fixed between adjoining fins of said plurality of flat plate shaped fins.

11. A heat sink as set forth in claim 10, wherein said tone noise diffusing strips are arranged in a direction along the flow of said cooling air.

12. A heat sink provided with a heat spreader and a plurality of flat plate shaped fins provided on the heat spreader and aligned in parallel adjacent to each other, wherein
the overall structure of said plurality of flat plate shaped fins is made a tone noise diffusing structure diffusing tone noise having substantially a single frequency generated from said flat plate shaped fins by cooling air to tone noise having a plurality of frequencies,
the tone noise diffusing structure comprised of a structure that makes alignment pitches between adjacent flat plate shaped fins non-uniform relative to each other.

13. A heat sink as set forth in claim 12, wherein said alignment pitches are made denser/sparser in accordance with a level of temperature distribution on said heat spreader.

14. A heat sink provided with a heat spreader and a plurality of flat plate shaped fins provided on the heat spreader and aligned in parallel adjacent to each other, wherein
the overall structure of said plurality of flat plate shaped fins is made a tone noise diffusing structure diffusing tone noise having substantially a single frequency generated from said flat plate shaped fins by cooling air to tone noise having a plurality of frequencies,
the tone noise diffusing structure comprised of a structure that changes heights of the flat plate shaped fins randomly so that top surfaces of the flat plate shaped fins do not become flat.

15. A heat sink as set forth in claim 8, wherein said wires are comprised of metallic wires or threads.
